(19) United States
(12) Patent Application Publication
(10) Pub. No.: US 2025/0034753 A1
(43) Pub. Date: Jan. 30, 2025

(54) Epitaxy Process Control in Semiconductor Manufacturing

(71) Applicant: Robert Bosch GmbH, Stuttgart (DE)

(72) Inventors: Stella Maris Van Eek, Langenbrueck (DE); Ulrich Potthoff, Dresden (DE)

(21) Appl. No.: 18/765,228

(22) Filed: Jul. 6, 2024

(30) Foreign Application Priority Data
Jul. 24, 2023 (DE) 10 2023 207 002.2

(51) Int. Cl. C30B 25/16; H01L 21/67

(52) U.S. Cl. CPC C30B 25/165; H01L 21/67253

(57) ABSTRACT

A method for process control of epitaxy for semiconductor component manufacturing includes (i) obtaining measurements of a semiconductor component processed according to a predetermined parameterization of the epitaxy process, and (ii) determining an adjusted parameterization of the epitaxy process for the subsequent semiconductor component by way of an R2R controller depending on the obtained measurements and depending on a process model. The process model is configured to predict a first manipulated variable that is a time, a first controlled variable, a layer thickness, and is additionally configured to predict a second controlled variable of a specific resistance depending on a second manipulated variable that is a gas flow.

This application claims priority under 35 U.S.C. § 119 to patent application no. DE 10 2023 207 002.2, filed on Jul. 24, 2023 in Germany, the disclosure of which is incorporated herein by reference in its entirety.

The disclosure relates to a control method of an R2R controller for epitaxy, which performs a multiple input multiple output R2R control, as well as a device, a computer program, and a machine readable storage medium configured to perform the method.

### BACKGROUND

It is known that R2R controllers receive measurements from processed wafers. The measurements are typically physical measurements on the wafer, but can also be virtual measurements. The physical measurements can also be referred to as product parameters. These include, e.g., in-line measurements, that can be measured on the processed product, preferably by way of physical measuring devices. In contrast, there are process parameters (processing time, polishing pressure, exposure rate, gas flow) that describe a manufacturing step (recipe) on the wafer.

By way of example, measurement methods include: layer thickness measurement (THK), e.g. spectroscopic ellipsometry of multiple superimposed transparent layers, structural measurement by atomic force microscopy (AFM), e.g. trench depth, imaging methods (CDSEM), e.g. geometric width, hole diameter, critical dimension, defect number and pattern, (DFU), resistance measurement (RES), specific resistance.

Based on the measurements, a recipe for the processing step (process step) of the at least one following wafer is then proposed by way of an R2R controller in order to possibly readjust the processing step accordingly if the measurements are not within a specified ideal range.

The processing step is controlled by way of piece goods control, meaning that the recipe for the subsequent processing step for a wafer or batch (batch of wafers) is influenced by the R2R controller. A recipe characterizes the respective manufacturing step or processing step, such as exposure, etching, depositing, or polishing, for example. However, the R2R controller does not intervene during the processing of the wafer/batch. This type of control is also referred to as R2R process control.

Run-to-run controllers for the manufacture of semiconductors are known. For example, see: Moyne, J. (2014). Run-to-run Control in Semiconductor Manufacturing, In: Baillieul, J., Samad, T. (eds) Encyclopedia of Systems and Control. London. Springer, https://doi.org/10.1007/978-1-4471-5102-9_255-1.

The R2R controller essentially serves to compensate for interference variables, e.g. longer-term drift in manufacturing, by way of corresponding recipe adaptations during subsequent processes in order to thereby maintain relevant in-line parameters at the respective desired target variable.

Furthermore, it is known that R2R controllers may be employed in epitaxy for process control. Here, the R2R controller serves to regulate the product layer thickness, which is referred to as the controlled variable (CV) of the R2R controller, based on the adjustable processing time, which is referred to as the manipulated variable (MV) of the R2R controller. That is to say, known R2R controllers for epitaxy represent SISO (single input single output) R2R control. Consequently, further formulation parameters, e.g. gas flows and lamp powers, are fixedly specified in the recipe.

However, it is problematic that through continuous and/or random interferences, e.g. aging of the EPI lamps over time, not only the epitaxy process result, such as the layer thickness, but also other target parameters such as specific resistance drift the number of sliplines so that complex manual recipe corrections are currently required. Each of these properties is so far set via individual test wafers in time consuming manual test procedures. In addition to the manual handling effort, this results in not inconsiderable, costly test wafer consumption. For example, a lamp power may be manually set in a few discrete steps, typically increasing monotonically over the life cycle without any back-correction.

Thus, an object of the disclosure is to provide continuous, automatic control of these costly consumable products with optimum utilization and minimum wear.

An advantage of the disclosure is a use of a common test wafer that runs through all process and measurement steps, and on which all three loops can be controlled together. Thus, cost savings by reducing the number of wafers and time savings by reducing the test procedure effort can be achieved. Furthermore, an optimum utilization of the lamp power (minimum wear) can be achieved across the life cycle of the lamp. Furthermore, the disclosure allows a continuous tuning, e.g. of the lamp power (only as much additional power as required, discrete steps are used manually) and thus more precise control. Moreover, the disclosure may perform an automatic back-correction (power reduction, not provided in manual procedure).

### SUMMARY

In a first aspect, the disclosure relates to a method for process control of epitaxy for semiconductor component manufacturing. Process control is carried out by way of an R2R controller, which regulates process parameters of the epitaxy process so that wafers processed with these process parameters, in particular semiconductor components on this wafer, are within a predetermined specification of the semiconductor components.

The method begins with obtaining measurements on one or a plurality of processed semiconductor components according to a predetermined process parameterization of the epitaxy process (P). The process parameterization may have been determined or otherwise predetermined by the R2R controller in a previous step. The measurements each characterize a property of the wafer/semiconductor component on which the epitaxy has an influence or which are changed by the epitaxy. The measurements preferably comprise at least the controlled variables of the process model mentioned below.

This is followed by a determination of an adjusted parameterization of the epitaxy process (P) for at least one semiconductor component, in particular one immediately downstream, using the R2R controller. The R2R controller determines the parameterization depending on the obtained measurements and a process model (P). The process model is configured to predict a first controlled variable (CV), a layer thickness (THK), depending on a first manipulated variable that is a time. The time may be a process time of epitaxy, i.e., as long as the wafer is under predetermined process conditions (e.g., temperature and gas flow). In addition, the process model is additionally configured to predict a second controlled variable of a specific resistance (RES) depending on a second manipulated variable that is a gas flow (GAS). The manipulated variables are parameters of the epitaxy process, which can be regulated by the R2R controller. The controlled variables should satisfy the specification of the semiconductor component after performing the epitaxy process. It should be noted that the process model is configured to either predict the first controlled variable using the first manipulated variable independent of the second manipulated variable, wherein the same applies analogously to the prediction of the second controlled variable, or to predict both controlled variables depending on both manipulated variables. It has become clear that there is no significant cross-effect between the two predictions and that they can be modeled by independent effect relationships in the process model.

The proposed method extends the process model of the known single input single output to multiple-input multiple-output R2R controller, whereby a particularly accurate control can be achieved precisely by the specific combination of said manipulated variables.

It is proposed that the second manipulated variable comprises a first and second gas flow (GAS1,GAS2). The first gas flow may comprise a gas flow of, for example, 400 sccm (standard cubic centimeter) (MDOPANT) and the second gas flow may comprise a gas flow of, for example, 20 sccm (standard cubic centimeter) (MDOPANTAUX).

Furthermore, it is proposed that the third manipulated variable comprises a first and second lamp power (POWER1,POWER2), wherein the first lamp power (POWER1) may be a relative value (TOPPOWER) that relates to an absolute power, e.g., 70.8%, wherein the second lamp power (PWOER2) is a relative value (BOTPOWER), e.g., then 17.2%.

It is further proposed that the R2R controller obtains a secondary condition with respect to the third controlled variable and takes it into account accordingly as a secondary condition when solving its internal optimization problem, wherein this secondary condition characterizes a maximum number of defects, which may occur at most after performing the process has been executed according to the R2R controller. The maximum number of defects is preferably greater than zero. Defects can be understood to mean any abnormalities caused by the epitaxy process.

Advantageous here is that the R2R controller can increase as well as reduce the lamp power due to this secondary condition. That is to say, this secondary condition gives the R2R controller a new degree of freedom, which enables it to freely readjust the lamp power.

For example, the lamp power can be set to 60% at the beginning and, during the production of the semiconductor components via the R2R controller, slowly be increased to a maximum power, e.g. 95% or 100%, in order to comply with this secondary condition, wherein the lamp power can be reduced by the controller in the meantime.

Furthermore, it is proposed that the number of defects is a number of sliplines. In this embodiment, the aforementioned secondary condition may be a max. number of sliplines (TAR), e.g., TAR<=1 or another value, which is preferably less than the highest number according to a specification for the semiconductor component.

Further advantageous embodiments of the first aspect of the disclosure are also set forth below.

In further aspects, the disclosure relates to an apparatus and to a computer program, which are each configured to perform the aforementioned methods, and to a machine-readable storage medium on which said computer program is stored.

### BRIEF DESCRIPTION OF THE DRAWINGS

Embodiments of the disclosure are explained in greater detail below with reference to the accompanying drawings. In the drawings:

FIG. 1 schematically shows a known R2R controller;

FIG. 2 schematically shows an R2R controller with an integrated process model;

FIG. 3 schematically shows process models for an R2R controller of epitaxy;

FIG. 4 schematically shows a heuristic trim curve;

FIG. 5 schematically shows an R2R control scheme 5×3; and

FIG. 6 schematically shows a flow diagram of an embodiment of a control method with an R2R control scheme 5×3.

### DETAILED DESCRIPTION

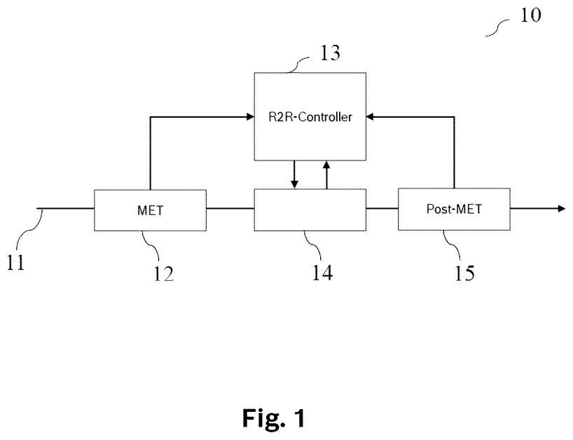

FIG. 1 schematically shows an information flow diagram 10 of a R2R controller 13, which is known from the prior art.

The information flow diagram 10 shows a process flow 11 for manufacturing a semiconductor component. In a first step, one or a plurality of physical measurements 12 are performed on a wafer. A measurement 12 may be a physical measurement on the wafer. The measurement results MET are then forwarded and provided to the R2R controller 13.

Depending on the measurement results MET, the R2R controller 13 can adjust a process step 14 for the wafer. In other words, the R2R controller 13 outputs an adjustment for the process step 14 depending on the measurement results MET so that, after performing the process step 14, the processed wafer ideally has product parameters within a specified range of values.

Optionally, after performing process step 14 according to the adjustment output by the R2R controller 13, one or a plurality of downstream physical measurements 15 can be performed on the processed wafer. The measurement results obtained post-MET can be provided to the R2R controller 13 as feedback so that the latter can provide better adjustments for subsequent process steps 14, depending on the subsequently obtained measurement results.

In summary, it can be said that the R2R process control according to FIG. 1 comprises a pre-measurement, processing, and optionally a follow-up measurement. The R2R controller 13 pursues a control target: setting process parameters (controlled variables) within specification limits based on a target value and automatically correcting, in a model-based and self-learning manner, target deviations by the targeted adaptation of manipulated variables, e.g. processing time, gas flows, etc.

The control law itself is typically a mathematical optimization problem with a target function, optionally with side conditions using stored state variables and a feedback principle based on system theory (closed loop control).

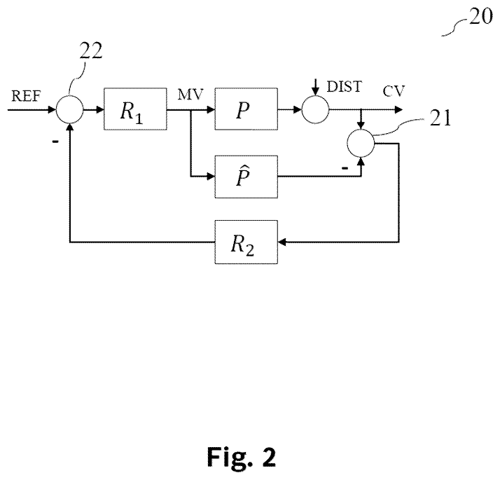

Preferably, the R2R control process is performed with an integrated process model. FIG. 2 shows an example of an R2R process control loop (20) with said integrated process model P. A controlled variable REF is specified for the process control. This is provided to the R2R controller R1, which determines a manipulated variable MV. A manufacturing process P is then performed according to the manipulated variable MV, wherein interference may occur during execution of the manufacturing process and/or subsequent measurement, depicted as interference variable DIST in FIG. 2. After a product has been processed according to the manufacturing process, it can be measured whether the variable CV to be controlled is within a target range or specification range.

Parallel to the manufacturing process P, the controlled variable CV is predicted with the process model \hat{P} depending on the manipulated variable MV. The process model \hat{P} is preferably a mathematical model, which models the relationships between the manipulated variable MV and the controlled variable CV. Preferably, the process model \hat{P} was created or parameterized based on data from tests. It is conceivable that the process model \hat{P} is a simple model, which reflects phenomena, in particular the basic behavior of the process. Alternatively, the process model \hat{P} may be a learned mathematical model, such as a Gaussian process or other machine learning system.

In the first information node 21, a difference between predicting the controlled variable CV by the process model \hat{P} and the (measured) controlled variable CV is determined. This difference may optionally be processed in a second controller R2. The second controller R2 may be a filter that performs smoothing and/or filters out noise. The interference variable DIST is thus advantageously minimized in the signal, which is, for example, a measurement noise. The second controller R2 may execute a moving average or exponentially smoothed weighting.

In the second information node 22, a difference between the guide variable REF and the signal from the first information node 21 or the processed signal of the second controller R2 is determined.

Depending on this difference, the first controller R1 regulates the manipulated variable MV. For example, if this difference is equal to 0, then the controller is not active. If the difference has a different value, then the controller is active. Preferably, the first controller R1 is a dead beat controller.

The process model \hat{P} may be an image of the process P, often a phenomenological input-output model, which does not necessarily have to be globally valid, but describes a behavior of the process P in the operating point.

In one embodiment, a thickness, specific resistance after processing by process P, can be measured as a controlled variable or product parameter. The first controller R1 pursues a control target: guide process parameters (controlled variables CV) to target value within specification limits (target). In this case, the first controller is automatically corrected, model-based, based on the difference of the second information node 22, target deviations by targeted adjustment of manipulated variables MV, e.g., processing time, gas flows, etc.

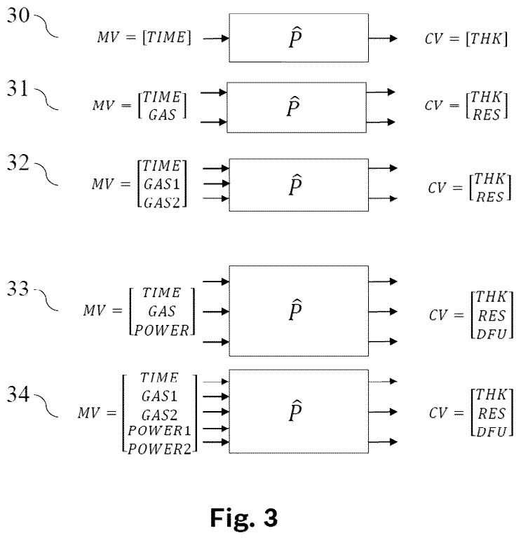

A first embodiment (30) of the process model \hat{P} in FIG. 3 shows a known process model for epitaxy control. The process model \hat{P} according to the first embodiment (30) predicts a layer thickening (THK) depending on a time (TIME).

In the following, an extension of the previous single input single output R2R control according to the first embodiment (30) is to be performed in order to achieve multiple input multiple output R2R controls.

In a second embodiment (31) of the process model, a novel first EPI control variant is proposed, which is a 2×2 multiple input multiple output process model \hat{P}. The 2×2 multiple input multiple output process model \hat{P} of the second embodiment (31) differs from the first embodiment (30) in that a gas flow GAS is additionally used as the manipulated variable MV and a specific resistance RES is used as the additional controlled variable CV. Accordingly, the time regulation (TIME) is extended to layer thickness (THK) by a further loop of gas flow (GAS) to specific resistance (RES). In general, the loops may be modeled independently or may be modeled dependent on each other in the process model.

In a third embodiment (32) of the process model, a novel second EPI control variant is proposed, which is a 3×2 multiple input multiple output process model \hat{P}. The 3×2 multiple input multiple output process model \hat{P} of the third embodiment (32) differs from the 2×2 multiple input multiple output process model \hat{P} of the second embodiment (31) in that a further gas flow GAS2 is used as an additional manipulated variable MV, as well as in that a dynamically calculated secondary condition is predetermined for the first controller R1, which defines an association between the gas flow GAS1 and further gas flow G2a*GAS1+b*GAS2=c, wherein the parameters a, b, c are real numbers. The parameters a, b, c may be derived empirically in advance from recipe settings and the corresponding measurements (design of experiments (DOE), test planning). The dynamically calculated secondary condition allows the further gas flow parameter (GAS2) to be a*GAS1+b*GAS2=c set as a function of the first gas flow parameter (GAS1).

It should be noted that the R2R controller can receive secondary conditions and preferably performs an optimization with respect to a quadratic cost function or quality criterion while taking one or more secondary conditions into account.

Preferably, a control loop for the gas flows GAS1, GAS2 to the specific resistance RES is defined or modeled. Stabilization of the specific resistance can thus be achieved, wherein the control can be carried out by the gas flow parameters GAS1 (e.g. MDOPANT) or an additional linearly dependent gas flow parameter GAS2 (e.g. MDOPANTAUX) as an adjustable recipe parameter.

In a fourth embodiment (33) of the process model, a novel third EPI control variant is proposed, which is a 3×3 multiple input multiple output process model \hat{P}. The 3×3 multiple input multiple output process model \hat{P} of the fourth embodiment (32) differs from the 2×2 multiple input multiple output process model \hat{P} of the second embodiment (31) in that, in addition to the control loop manipulated variable MV of the gas flow GAS on the controlled variable CV of the specific resistance RES, a further control loop is additionally defined, which defines a lamp power POWER on the controlled variable CV of a number of sliplines DFU as the manipulated variable MV.

Preferably, a secondary condition for the first controller R1 is defined for the further control loop lamp power POWER to the number of sliplines DFU. To minimize the number of sliplines, continuous control of the lamp power (POWER) is used. The secondary condition may then comprise a max. number of sliplines, e.g. TAR<1.

In a fifth embodiment (34) of the process model, a novel, fourth EPI control variant is proposed, which is a 5×3 multiple input multiple output process model \hat{P}. The 5×3 multiple input multiple output process model \hat{P} of the fifth embodiment (32) differs from the 3×2 multiple input multiple output process model of the third embodiment (32) in that the manipulated variable MV is given a lamp power POWER by two variables POWER1 and POWER2 and is defined as a control loop on the number of sliplines DFU. For example, TOPPOWER/BOTPOWER is used as POWER1/POWER2 as an adjustable recipe parameter.

Furthermore, as in the fourth embodiment (33), the secondary condition of a maximum number (TAR) of sliplines DFU for the first controller R1 is used. Additionally, a dynamically calculated secondary conditiond*POWER1+e*POWER2=f, where parameters are d, e, f real numbers, can be used. The parameters d, e, f are typically predetermined as system settings, e.g. d=1, e=−4 and f=0.5.

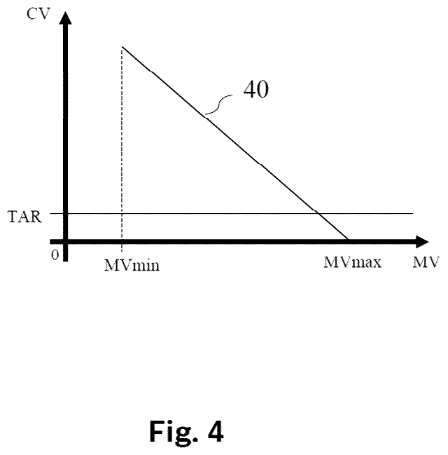

FIG. 4 depicts a heuristic adjustment curve for the relationship of POWER on sliplines. The manipulated variable MV is plotted on the x-axis, for example, here the lamp power. On the y-axis, the controlled variable CV, here the number of sliplines, is plotted. TAR is the target value of the controlled variable, here max. number of sliplines. TAR is typically 1, other values >0 are also conceivable. The advantage of using TAR <1 as a secondary condition is that it allows a back-correction of the controller. That is to say, the controller can both increase and advantageously reduce the lamp power.

For the relationship between manipulated variable MV (e.g. POWER1/POWER2=POWERRATIO) and controlled variable CV (number of sliplines), a straight line 40 with a negative slope has resulted, i.e. MV increase reduces CV.

It is conceivable that the manipulated variable can only be set within a predeterminable range: Mvmin<MV<MVmax.

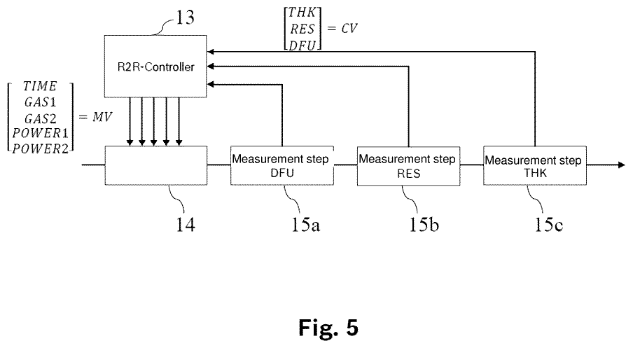

FIG. 5 schematically shows an R2R control scheme 5×3 according to the fifth embodiment 34 of the process model.

The R2R controller 13 differs from FIG. 1 in that it now receives more measurements as input and can regulate a plurality of manipulated variables MV based on these measurements.

The process flow in FIG. 5 differs from the process flow of FIG. 1 in that the POST-MET step 15 has a plurality of different measurements. The controlled variables CV are recorded in the individual measurements 15a-15c.

Measurements 15a-15c may be performed in sequence as shown in FIG. 5. Alternatively, a parallel measurement is conceivable.

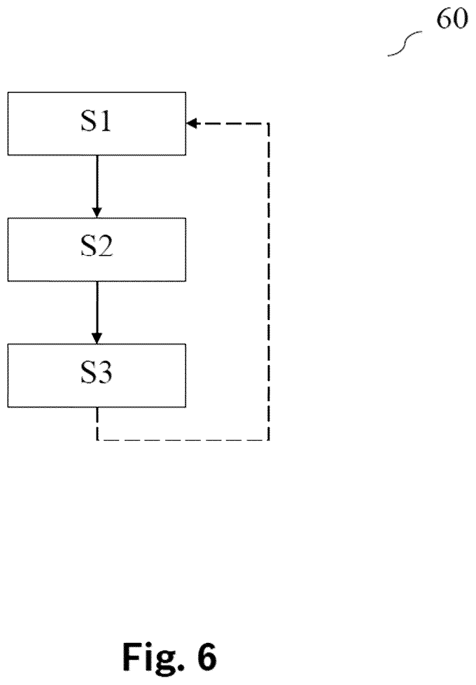

FIG. 6 schematically shows a flow chart 40 of an embodiment of a control method of the R2R controller 13 based on the process models 30-34 above.

The method starts with providing or obtaining (S1) measurements (15a-15c) of a semiconductor component processed according to a predetermined parameterization of the epitaxy process (P).

In the subsequent step S2, a determination (S2) of an adjusted parameterization of the epitaxy process (14) for the subsequent semiconductor component is carried out by way of an R2R controller (13) depending on the obtained measurements and a process model (P). The process model is one of the process models 30-34.

In the following step S3, the process is controlled according to the parameterization from step S2. Optionally, the measurements 15 can be performed in step S3.

Optionally, steps S1-S3 may be performed again by providing the measurements from step S3 to step S1.

What is claimed is:

1. A method for process control of an epitaxy for semiconductor component manufacturing, comprising:
obtaining measurements of a semiconductor component processed according to a predetermined parameterization of the epitaxy process; and
determining an adjusted parameterization of the epitaxy process for a subsequent semiconductor component by way of an R2R controller depending on the obtained measurements and a process model,
wherein the process model is configured to predict a first controlled variable that is a layer thickness depending on a first manipulated variable that is a time, and
wherein the process model is additionally configured to predict a second controlled variable of a specific resistance depending on a second manipulated variable which is a gas flow.

2. The method according to claim 1, wherein:
the second manipulated variable includes a first gas flow and a second gas flow, and
the R2R controller takes into account a first secondary condition characterizing a ratio of the first gas flow to the second gas flow.

3. The method according to claim 1, wherein the process model is additionally configured to predict a third controlled variable of a number of defects depending on a third manipulated variable which is a lamp power.

4. The method according to claim 3, wherein:
the third manipulated variable includes a first lamp power and a second lamp power,
the first lamp power is a first relative power,
the second lamp power is a second relative power, and
the R2R controller takes into account a second secondary condition which characterizes a ratio of the first lamp power to the second lamp power.

5. The method according to claim 3, wherein:
the R2R controller receives a third secondary condition with respect to the third controlled variable, and
the third secondary condition characterizes a maximum number of defects that may occur at most after the execution of the process.

6. The method according to claim 1, wherein:
the process model is a parameterizable model, and
the parameterization is predetermined.

7. An apparatus which is configured to perform the method according to claim 1.

8. A computer program comprising instructions which, when the program is performed by a computer, cause the computer to carry out the method according to claim 1.

9. A machine-readable storage medium on which the computer program according to claim 8 is stored.

10. The method according to claim 1, wherein:
the process model is a parameterizable model, and
the parameterization is determined based on experiments.
